(19) United States
(12) Patent Application Publication
(10) Pub. No.: US 2013/0287967 A1
(43) Pub. Date: Oct. 31, 2013

(54) Method Of Making A Golf Ball With A Superhydrophobic Surface

(71) Applicant: Takahisa Ono, Fujisawa (JP)

(72) Inventor: Takahisa Ono, Fujisawa (JP)

(73) Assignee: NIKE, INC., Beaverton, OR (US)

(21) Appl. No.: 13/460,506

(22) Filed: Apr. 30, 2012

(51) Int. Cl. C23C 16/22; C23C 16/50

(52) U.S. Cl. 427/569; 427/248.1

(57) ABSTRACT

A method of making a golf ball with a superhydrophobic coating is disclosed. A superhydrophobic coating may increase the flight distance achieved by the golf ball. Furthermore, providing a golf ball with a superhydrophobic coating may help keep moisture off the surface of the golf ball. The superhydrophobic coating may include one of tetrafluoromethane (CF4), hexafluoromethane (C2F6), or octafluoropropane (C3F8). The method may include a plasma enhanced chemical vapor deposition process.

### BACKGROUND

The present invention relates generally to a method of making a golf ball with a superhydrophobic surface.

The game of golf is an increasingly popular sport at both the amateur and professional levels. A wide range of technologies related to the manufacture and design of golf balls are known in the art. Such technologies have resulted in golf balls with a variety of play characteristics. For example, different dimple characteristics may affect the aerodynamic properties of the golf ball during flight, or a difference in the hardness of the cover layer may affect the rate of backspin. Consequently, different golfers may desire to use different golf balls having surfaces suiting the golfers' individual abilities. It would be advantageous to be able to make a golf ball that could be customized to meet different golfers' needs.

### SUMMARY

A method of making a golf ball with a superhydrophobic coating is disclosed. A superhydrophobic coating may increase the flight distance achieved by the golf ball. Furthermore, providing a golf ball with a superhydrophobic coating may help keep moisture off the surface of the golf ball. The superhydrophobic coating may include one of tetrafluoromethane (CF4), hexafluoromethane (C2F6), or octafluoropropane (C3F8). The method may include a plasma enhanced chemical vapor deposition process.

In one aspect the disclosure provides a method of making a golf ball. The method may include a step of placing a golf ball in a chamber. The method may include a step of providing a gas plasma inside the chamber. In some embodiments, the method may include a step of providing one of tetrafluoromethane (CF4), hexafluoromethane (C2F6), or octafluoropropane (C3F8) gas inside the chamber to form a superhydrophobic coating on the outer surface of the golf ball. The method may include a step of creating a vacuum inside the chamber. In some embodiments, the method may include a step of setting the pressure inside the chamber to a pressure ranging from about 200 mTorr to about 10 Torr. In some embodiments, the method may include a step of setting the temperature inside the chamber to a temperature ranging from about 10 degrees Celsius to about 30 degrees Celsius. In some embodiments, the melting point of the golf ball used in the disclosed method may have a temperature of about 60 degrees Celsius or greater.

In one aspect the disclosure provides a method of making a golf ball. The method may include a step of forming a core. In some embodiments, the method may include a step of forming a cover layer surrounding the core. The method may include a step of placing a golf ball in a chamber. The method may include a step of providing one of tetrafluoromethane (CF4), hexafluoromethane (C2F6), or octafluoropropane (C3F8) gas inside the chamber to form a superhydrophobic coating on the outer surface of the golf ball. The method may include a step of creating a vacuum inside the chamber. The method may include a step of providing a plasma inside the chamber. In some embodiments, the step of forming a core may include forming a core includes injection molding a core. The step of forming a core may include forming an inner core and compression molding an outer core surrounding the inner core. The step of forming a cover layer includes forming between one and three cover layers. The step of forming a cover layer may include injection molding the cover layer around the core.

In one aspect the disclosure provides a method of making a golf ball. The method may include a step of manufacturing a finished golf ball. The method may include a step of providing the finished golf ball to a retailer. The method may include a step of providing the retailer with instructions for customizing the finished golf ball with a superhydrophobic coating on the outer surface of the golf ball. In some embodiments, the method may include a step of providing the retailer with equipment capable of performing plasma enhanced chemical vapor deposition process. The instructions for customizing the finished golf ball may include placing the finished golf ball in a chamber and providing one of tetrafluoromethane (CF4), hexafluoromethane (C2F6), or octafluoropropane (C3F8) gas inside the chamber. The instructions for customizing the finished golf ball may include providing a plasma inside the chamber. The instructions for customizing the finished golf ball may include creating a vacuum inside the chamber. In some embodiments, the method may include a step of setting the pressure inside the chamber to a pressure ranging from about 200 mTorr to about 10 Torr. In some embodiments, the instructions for customizing the finished golf ball may include setting the temperature inside the chamber to a temperature ranging from about 10 degrees Celsius to about 30 degrees Celsius. In some embodiments, the step of manufacturing a finished ball may include forming a golf ball core and a golf ball cover surrounding the golf ball core.

Other systems, methods, features and advantages of the invention will be, or will become, apparent to one of ordinary skill in the art upon examination of the following figures and detailed description. It is intended that all such additional systems, methods, features and advantages be included within this description and this summary, be within the scope of the invention, and be protected by the following claims.

### BRIEF DESCRIPTION OF THE DRAWINGS

The invention can be better understood with reference to the following drawings and description. The components in the figures are not necessarily to scale, emphasis instead being placed upon illustrating the principles of the invention. Moreover, in the figures, like reference numerals designate corresponding parts throughout the different views.

FIG. 1 is an exemplary golf ball before and after a coating material has been applied;

FIG. 2 is a cross section of the golf ball of FIG. 1, before and after a coating material has been applied;

FIG. 3 is an illustration of contact angles between surfaces and water that may be used to quantify whether the surface is hydrophilic, hydrophobic, or superhydrophobic;

FIG. 4 is a flowchart showing an exemplary method of applying a superhydrophobic coating to a golf ball;

FIG. 5 is a flowchart showing an exemplary method of making a golf ball; and

FIG. 6 is a flowchart showing an exemplary process by which a golf ball may be customized.

### DETAILED DESCRIPTION

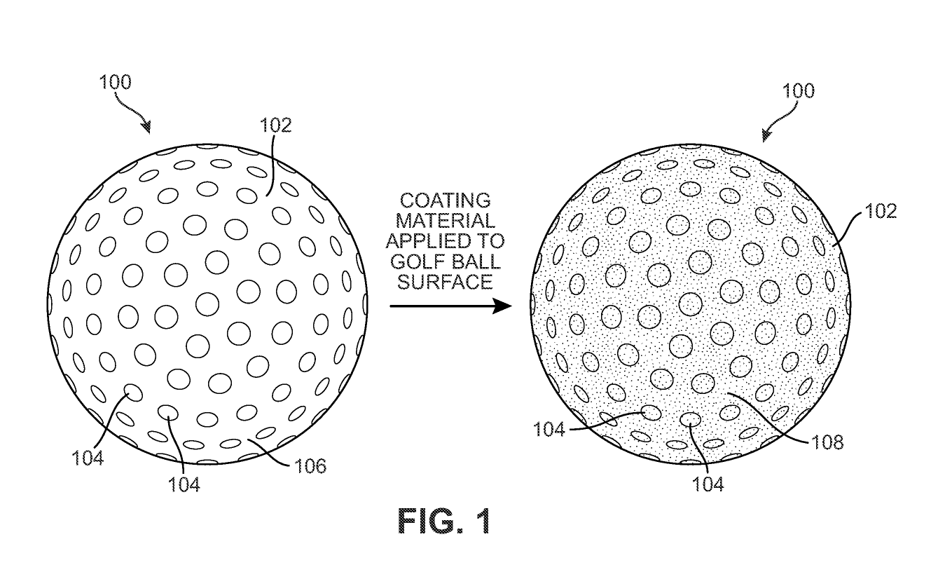

Golf balls may typically include a core substantially surrounded by one or more layers. For example, a golf ball may be of a two-piece construction, having only a core and a cover layer, or a golf ball may have one or more intermediate layers located between the core and the cover layer. Golf balls within the scope of this disclosure may be of a one-piece construction, a two-piece construction, or may have additional intermediate layers between the core and cover layer. For example, golf balls within the scope of this disclosure may be of a four-piece construction. Referring to FIG. 1, a golf ball 100 may include a cover layer 102. Cover layer 102 may include dimples 104 and a land area 106. Dimples 104 may generally be arranged on cover layer 102 in any pattern, as may be known in the art of golf balls. Various known dimple packing patterns are known in the art. Dimples 104 may generally be of any shape, such as circular, triangular, or multi-sided. Dimples 104 may be of uniform shape and size, or the dimple pattern may be made up of two or more different types of dimples having (for example) different sizes or different shapes. Land area 106 may be part of cover layer 102 that separates at least two dimples 104 and that is not indented or otherwise part of the dimple. Generally, land area 106 may be the “ridge” or “fret” between adjoining dimples 104.

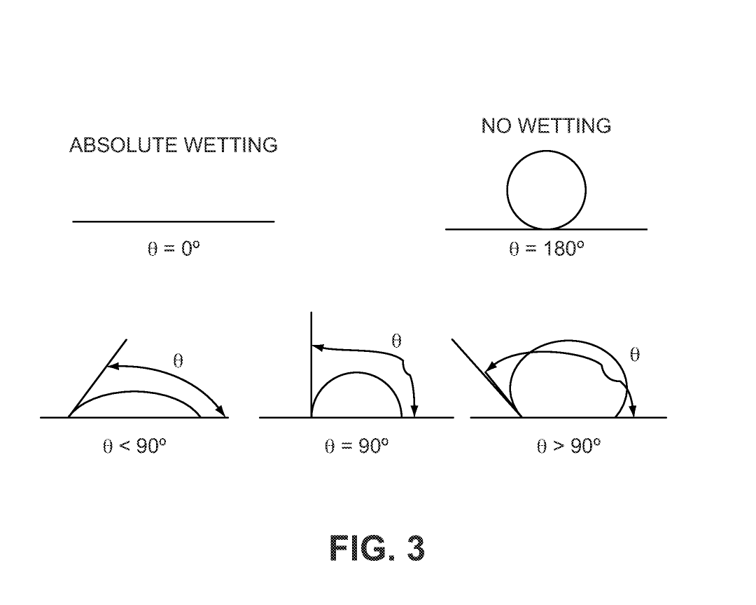

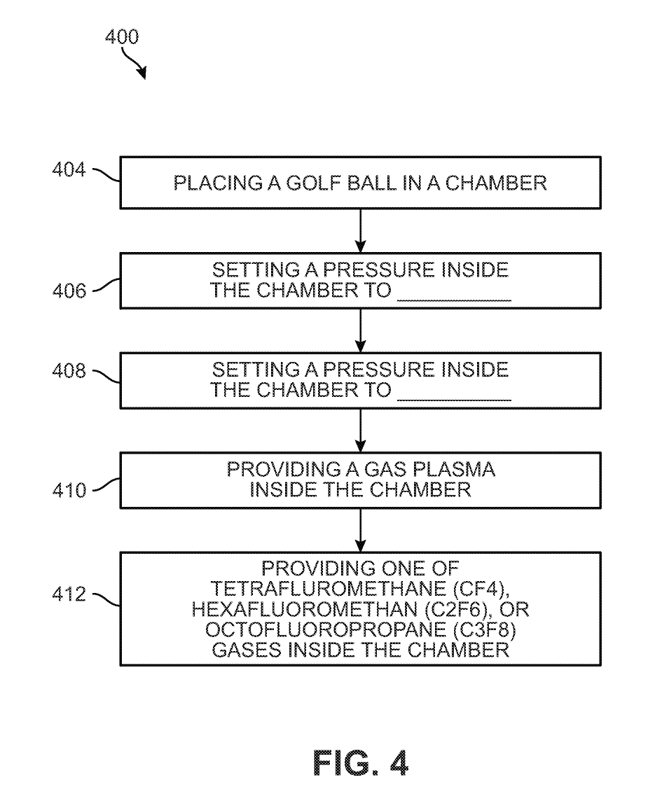

In the embodiment shown in FIG. 1, a coating material 108 may be applied to the surface of the golf ball. In such an embodiment, coating material 108 may be superhydrophobic. Cover layer 102 may be treated to become superhydrophobic by the disclosed method, which is discussed below with reference to FIG. 4. Hydrophobic means repelling water. FIG. 3 is an illustration of contact angles between surfaces and water that may be used to quantify whether the surface is hydrophilic, hydrophobic, or superhydrophobic. A surface that makes a contact angle with water (“θ”) of less than 90 degrees is considered hydrophilic. A surface that makes a contact angle with water (“θ”) of more than about 90 degrees is considered hydrophobic. A surface that makes a contact angle with water (“θ”) of more than about 150 degrees is considered superhydrophobic. The relative hydrophilicity of two surfaces can be determined by comparing the contact angles between the surfaces and water. For example, a surface that makes a contact angle with water of 60 degrees is less hydrophilic than a surface that makes a contact angle with water of 30 degrees. Decreasing the hydrophilicity of the surface of a golf ball may reduce the drag acting on the golf ball as it flies through the air. Reducing drag may make air flow around the ball smooth and may cause the golf ball to achieve increased flight distance. Thus, providing a golf ball with a superhydrophobic surface may increase the flight distance achieved by the golf ball. Furthermore, providing a golf ball with a superhydrophobic coating may help keep moisture off the surface of the golf ball. In wet playing conditions, golf balls tend to become slick, making it difficult to accurately hit, impart force to, and/or impart spin to the golf balls. Keeping moisture from settling on the golf ball may prevent the golf ball from becoming slick, thereby improving accuracy, distance, and/or control.

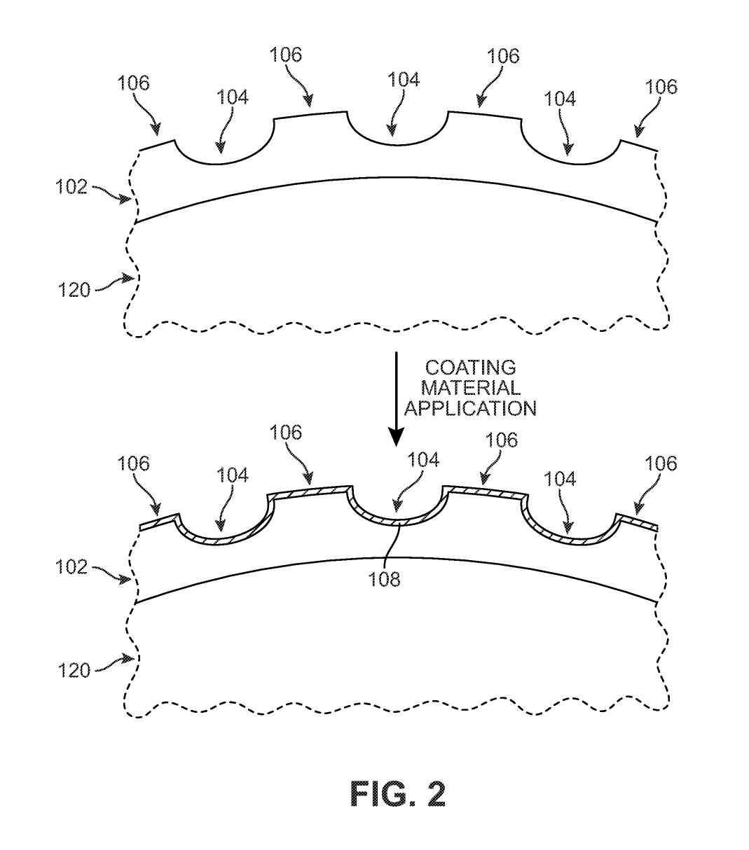

FIG. 2 is a cross section of golf ball 100 before and after coating material 108 has been applied. In some embodiments, coating material 108 may have a thickness within a range of 1 μm and 3 mm. For example, in some embodiments, coating material 108 may have a thickness of 5 μm. In some embodiments, coating material 108 may have a thickness of 0.5 mm. In some embodiments, coating material may have a thickness of 1 mm. In some embodiments, the thickness of coating material 108 may be selected based on a variety of factors. For example, the thickness of coating material 108 may be selected based on the type of cover layer material used and/or the type of coating material used. In some embodiments, for example, as shown in FIG. 2, the profile of coating material 108 may have a uniform thickness. The treatment time may be adjusted to achieve a certain thickness of coating material 108. For example, a longer treatment time may result in a thicker coating.

FIG. 4 is a flowchart showing an exemplary method 400 of making a golf ball. Method 400 may include steps for applying a superhydrophobic coating to a golf ball. In some embodiments, method 400 may include a plasma enhanced chemical vapor deposition process. In some embodiments, method 400 may include a step 404 of placing a golf ball in a chamber. For example, the chamber may be a plasma vapor deposition chamber provided with one or more microwave sources. The number and size of the microwave sources may be selected based on the size of the chamber and/or the positioning of the microwave sources. In some embodiments, a magnetron may be disposed on the microwave source(s). In some embodiments, the magnetron may output up to about 1200 Watts of power. In some embodiments, the chamber may include a waveguide. In another example, the chamber may be a plasma vapor deposition chamber containing an electrode and at least one conductive wall, where the chamber is sealed to contain the gas to form the deposited layer. In another embodiment, the chamber may be a sealed plasma vapor deposition chamber containing a parallel plate reactor. Examples of plasma systems that may be used to perform the disclosed method include the V200-G, V100-G, and V55-G, all commercially available from PINK GmbH.

In some embodiments, method 400 may include a step 404 of setting a pressure inside the chamber to a pressure ranging from about 200 mTorr to about 10 Torr. Such a pressure may create a vacuum inside the chamber. A vacuum may help control gas and vapor composition. Furthermore, a vacuum may facilitate mass flow control into the chamber.

Method 400 may include a step 406 of setting a temperature inside the chamber to a temperature ranging from about 10 degrees Celsius to about 30 degrees Celsius. Since this temperature range includes room temperature, method 400 may be performed without deliberately setting the temperature inside the chamber. The temperature inside the chamber may be so low during the coating process because the plasma may be ignited at a low pressure. Igniting plasma at a low pressure may create a cold plasma, or nonthermal plasma. In some embodiments, the melting point of the golf ball used in the disclosed method may have a temperature of about 60 degrees Celsius or greater. Thus, the low temperature used during the coating process may prevent the golf ball from melting or deforming. The temperature may be selected based on a variety of factors. For example, the temperature may be selected based on the melting point of the golf ball materials and/or the threshold temperature necessary to help control gas and vapor composition. For example, SURLYN, a resin produced by DuPont Corporation, is a typical golf ball cover material. The various grades of SURLYN have melt temperatures of between 70 degrees Celsius and 100 degrees Celsius. In embodiments where the cover of the golf ball is made of SURLYN, the temperature inside the chamber may be less than 70 degrees Celsius to avoid melting the cover material. In some embodiments, the temperature inside the chamber may be less than the Vicat softening temperature of the golf ball cover material to avoid altering the properties of the cover material and/or the damaging the dimple pattern. For example, the various grades of SURLYN have a Vicat softening point of between 47 degrees Celsius and 74 degrees Celsius. In embodiments where the cover of the golf ball is made of SURLYN, the temperature inside the chamber may be less than 47 degrees Celsius.

Method 400 may include a step 408 of providing a gas plasma inside the chamber. A plasma environment may aid in activating gaseous species and in decomposition of chemical vapor precursors. Method 400 may include a step 410 of providing one of tetrafluoromethane (CF4), hexafluoromethane (C2F6), or octafluoropropane (C3F8) gases inside the chamber. In some embodiments, step 410 may include spraying the gases. These gases may be used to clean the golf ball before the coating the golf ball and/or these gases may be used to coat the golf ball.

Method 400 may include a step 412 of depositing one of tetrafluoromethane (CF4), hexafluoromethane (C2F6), or octafluoropropane (C3F8) onto the surface of the golf ball to form a superhydrophobic coating. During step 412, the tetrafluoromethane (CF4), hexafluoromethane (C2F6), or octafluoropropane (C3F8) gases inside the chamber may transform into a solid making up a coating on the surface of the golf ball. In a plasma vapor deposition process, this is typically achieved by applying a current (typically alternating current) or a radio frequency. In some embodiments, the current may be about 60 Hz. The radio frequency may be any frequency capable of achieving the desired film thickness. In some embodiments, a magnetron may produce the radio frequency. In some embodiments, the radio frequency may be between about 10 kHz to about 3.0 GHz. For example, the radio frequency may be about 2.45 GHz. In some embodiments, the frequency may be about 13.56 MHz. For example, the superhydrophobic coating may be coating material 108, shown in FIGS. 1 and 2.

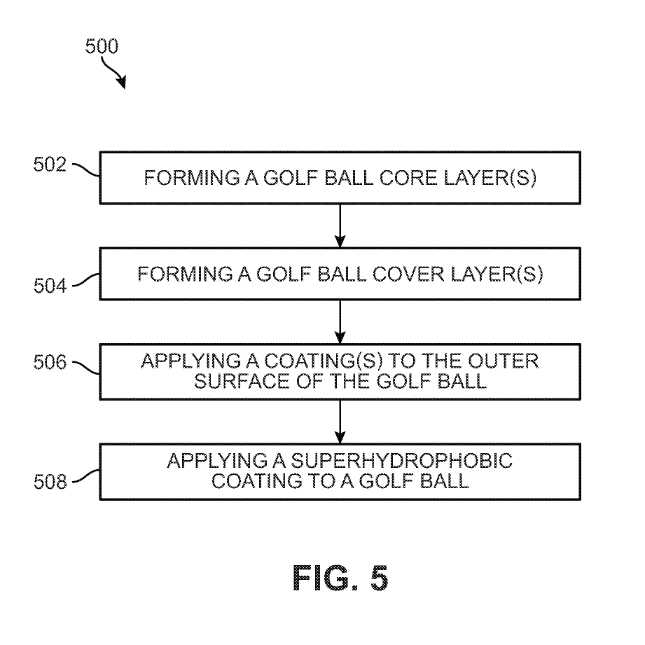

FIG. 5 is a flowchart showing an exemplary method 500 of making a golf ball. In some embodiments, method 500 may include a step 502 of forming a golf ball core layer(s). In some embodiments, forming a golf ball core layer may include forming a single core or an inner core layer. In some embodiments, forming a single core or an inner core layer may include injection molding core material into a substantially sphere shape. In some embodiments, forming a single core or an inner core layer may include compression molding core material into a substantially sphere shape. In some embodiments, step 502 may include forming one or more outer core layers surrounding an inner core layer. In some embodiments, forming an outer core layer may include compression molding outer core material around the inner core layer. In some embodiments, forming an outer core layer may include injection molding outer core material around the inner core layer. In some embodiments, the outer core layer may be made by hot-press molding process. The surface of the inner core layer may be roughened before forming the outer core layer around the inner core layer to increase adhesion between the inner core layer and the outer core layer.

In some embodiments, method 500 may include a step 504 of forming a golf ball cover layer(s). For example, in some embodiments, step 504 may include making a mantle or a single cover layer. In some embodiments, the mantle or single cover layer may be formed by injection molding cover material around the outer core layer. In some embodiments, the inner core layer surface may be pre-coated with an adhesive or pre-treated with chemical(s) before molding the mantle or single cover layer to enhance the durability of the golf ball and enable a high rebound. In some embodiments, step 504 may include forming an outer cover layer surrounding the mantle. For example, an outer cover layer may be injection molded around the mantle.

After the single cover layer or outer cover layer is molded, to make the outer surface of the golf ball have a uniform finish, excess material leftover from injection molding, such as, for example, a flash line, may be removed through trimming, grinding, buffing, and/or other processes. The golf ball may then undergo finishing work. For example, in some embodiments, method 500 may optionally include a step 506 of applying a coating(s) to the outer surface of the golf ball. In some embodiments, step 506 may include spraying the golf ball with a protective coating or a coating that imparts aerodynamic properties to the golf ball. These coating materials may be liquid when they are applied to the ball. The golf ball may be stationary or may be spinning before, during, and/or after the coating material is applied to the golf ball.

Method 500 may include a step 508 of applying a superhydrophobic coating to the outer surface of the golf ball. Step 508 may include any of the steps of method 400, described above. In some embodiments, step 508 may replace step 506. In other embodiments, the superhydrophobic coating applied during step 508 may be applied over the coating applied during step 506.

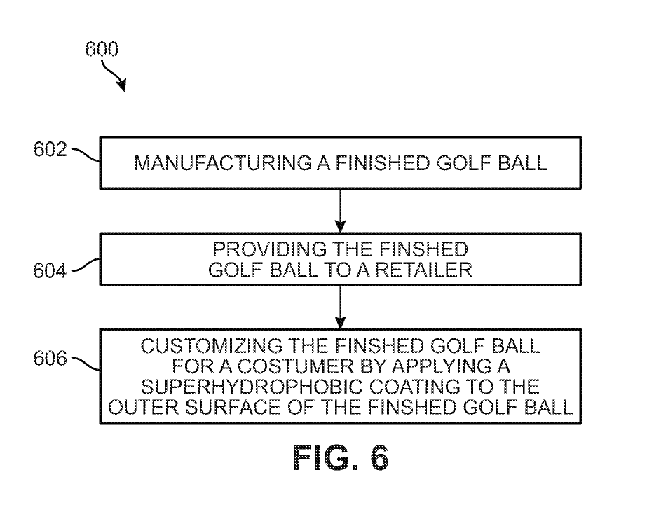

FIG. 6 is a flowchart showing an exemplary method 600 of making a golf ball. Step 602 may include manufacturing a finished golf ball. For example, step 602 may include any of the steps of method 500, described above. A finished golf ball may be a golf ball that includes all layers and components necessary for the golf ball to be used by a golfer in a game of golf. For example, golf ball 100 shown in FIG. 1 may be a finished golf ball before coating material 108 is applied to golf ball 100. In some embodiments, the finished golf ball may be a one-piece construct. In other embodiments, the finished golf ball may be a two-piece construct, having a core and a cover layer. The finished golf ball may include any number of layers and/or coatings.

Method 600 may include a step 604 of providing the finished golf ball to a retailer. The finished golf ball may be a golf ball sold by the retailer as is. However, the retailer may also customize the finished golf ball for a golfer. For example, in some embodiments, method 600 may include a step 606 of customizing the finished golf ball for a golfer by applying a superhydrophobic coating to the outer surface of the finished golf ball. Step 606 may include any of the steps of method 400. To perform these steps, the retailer may have access to equipment capable of performing plasma enhanced chemical vapor deposition process. In some embodiments, method 600 may include a step of providing such equipment at the retailer's location. In some embodiments, the retailer's location may be a store and/or a ball fitting facility. In some embodiments, method 600 may include providing the retailer with instructions for performing step 606. In another example, the manufacturer may have access to such equipment and the retailer may request that the manufacturer customize the finished golf ball. In such embodiments, the manufacturer may perform step 606. In some embodiments, the golfer may request that the manufacturer customize the finished golf ball. For example, the finished ball may be available for sale online at a website. In such an example, the golfer may be able to use a computer to access the website. The website may provide the golfer with the option of requesting that the manufacturer customize the finished golf ball when the golfer orders the finished golf ball online. Thus, the golfer may select the finished ball on the website and the golfer may select the option of requesting that the manufacturer customize the finished golf ball.

In some embodiments, the retailer may use ball fitting services to determine the needs of a golfer. For example, the retailer may use a ball launch monitor to analyze the golfer's swing. The retailer may use this analysis to determine which type of ball would give the best performance for the golfer's swing. For example, a golfer may want a golf ball that maximizes distance. From the swing data of that golfer, the retailer may determine that a golf ball having a superhydrophobic coating most enhances this particular golfer's distance. In some situations, the retailer may have a ball in stock that already has a superhydrophobic coating. If this is not the case, the retailer may be able to customize a finished golf ball for this golfer or to request that the manufacturer customize a finished golf ball for this golfer.

It is understood that any of the steps disclosed above may be performed in any order. For example, step 406 may be performed at the same time as step 408. In another example, step 606 may be performed before step 604.

While various embodiments of the invention have been described, the description is intended to be exemplary, rather than limiting and it will be apparent to those of ordinary skill in the art that many more embodiments and implementations are possible that are within the scope of the invention. Accordingly, the invention is not to be restricted except in light of the attached claims and their equivalents. Also, various modifications and changes may be made within the scope of the attached claims.

1. A method of making a golf ball, comprising:
placing a golf ball in a chamber;
providing a gas plasma inside the chamber; and
providing one of tetrafluoromethane (CF4), hexafluoromethane (C2F6), or octafluoropropane (C3F8) gas inside the chamber to form a superhydrophobic coating on the outer surface of the golf ball.

2. The method of making a golf ball according to claim 1, further comprising:
creating a vacuum inside the chamber.

3. The method of making a golf ball according to claim 2, further comprising:
setting the pressure inside the chamber to a pressure ranging from about 200 mTorr to about 10 Torr.

4. The method of making a golf ball according to claim 1, further comprising:
setting the temperature inside the chamber to a temperature ranging from about 10 degrees Celsius to about 30 degrees Celsius.

5. The method of making a golf ball according to claim 1, wherein the melting point of the golf ball is about 60 degrees Celsius or greater.

6. A method of making a golf ball, comprising:
forming a core;
forming a cover layer surrounding the core;
placing a golf ball in a chamber; and
providing one of tetrafluoromethane (CF4), hexafluoromethane (C2F6), or octafluoropropane (C3F8) gas inside the chamber to form a superhydrophobic coating on the outer surface of the golf ball.

7. The method of making a golf ball according to claim 6, further comprising:
creating a vacuum inside the chamber.

8. The method of making a golf ball according to claim 6, further comprising:
providing a plasma inside the chamber.

9. The method of making a golf ball according to claim 6, wherein forming a core includes injection molding a core.

10. The method of making a golf ball according to claim 6, wherein forming a core includes forming an inner core and compression molding an outer core surrounding the inner core.

11. The method of making a golf ball according to claim 6, wherein forming a cover layer includes forming between one and three cover layers.

12. The method of making a golf ball according to claim 6, wherein forming a cover layer includes injection molding the cover layer around the core.

13. A method of making a golf ball, comprising:
manufacturing a finished golf ball;
providing the finished golf ball to a retailer; and
providing the retailer with instructions for customizing the finished golf ball with a superhydrophobic coating on the outer surface of the golf ball.

14. The method of making a golf ball according to claim 13, further comprising:
providing the retailer with equipment capable of performing plasma enhanced chemical vapor deposition process.

15. The method of making a golf ball according to claim 13, wherein the instructions for customizing the finished golf ball include placing the finished golf ball in a chamber and providing one of tetrafluoromethane (CF4), hexafluoromethane (C2F6), or octafluoropropane (C3F8) gas inside the chamber.

16. The method of making a golf ball according to claim 15, wherein the instructions for customizing the finished golf ball include providing a plasma inside the chamber.

17. The method of making a golf ball according to claim 16, wherein the instructions for customizing the finished golf ball include creating a vacuum inside the chamber.

18. The method of making a golf ball according to claim 17, wherein the instructions for customizing the finished golf ball include setting the pressure inside the chamber to a pressure ranging from about 200 mTorr to about 10 Torr.

19. The method of making a golf ball according to claim 15, wherein the instructions for customizing the finished golf ball include setting the temperature inside the chamber to a temperature ranging from about 10 degrees Celsius to about 30 degrees Celsius.

20. The method of making a golf ball according to claim 13, wherein the step of manufacturing a finished ball includes forming a golf ball core and a golf ball cover surrounding the golf ball core.
